(19) United States
(12) Patent Application Publication
(10) Pub. No.: US 2005/0018732 A1
(43) Pub. Date: Jan. 27, 2005

(54) Uncooled and high temperature long reach transmitters, and high power short reach transmitters

(76) Inventors: Aaron Bond, Orefield, PA (US); Newton C. Frateschi, Campinas (BR); Jiaming Zhang, Breingsville, PA (US)

Correspondence Address: RATNERPRESTIA, P O BOX 980, VALLEY FORGE, PA, 19482-0980, US

(21) Appl. No.: 10/741,494

(22) Filed: Dec. 19, 2003

Related U.S. Application Data
(60) Provisional application No. 60/434,629, filed on Dec. 19, 2002.

(51) Int. Cl. H01S 5/00; H01L 31/075

(52) U.S. Cl. 372/50; 257/458

(57) ABSTRACT

A method for improving the reliability of an uncooled long reach optical transmitter operating substantially at a predetermined output power. The uncooled long reach optical transmitter in this method includes a laser, an SOA and a modulator. The laser is operated to produce a reduced power laser beam, thereby improving the laser reliability. The SOA bias current is controlled so that the SOA amplifies the reduced power laser beam to substantially maintain the predetermined output power. The SOA is sufficiently long to provide this amplification, while maintaining a reduced current density within the SOA, thereby improving the SOA reliability. Small signal chirp parameters are measured for two bias voltages of the modulator. A linear function of the modulator bias voltage versus temperature is determined. The modulator bias voltage as a function of temperature is adjusted to maintain a constant dispersion penalty for data transmission.

This application is related to and claims the benefit of U.S. Provisional Application No. 60/434,629 entitled UNCOOLED AND HIGH TEMPERATURE LONG REACH TRANSMITTERS, AND HIGH POWER SHORT REACH TRANSMITTERS filed on Dec. 19, 2002.

### FIELD OF THE INVENTION

The present invention concerns a design for producing uncooled, high-powered transmitters and transponders for optical communications systems. This design may also allow the use of reduce form factor packages.

### BACKGROUND OF THE INVENTION

Optical transmitters and transponders are used extensively in many communication systems, which may extend over large distances. It is desirable to be able to transmit optical signals over these large distances. Signal loss within optical fibers limits the distance that an optical signal of a certain power level may be transmitted effectively. Scattering and absorption of the light may be a major source of signal loss in optical fibers. In-line amplifiers to boost the optical signal may increase the distance the signal may be transmitted, but these amplifiers may amplify noise as well as the signal, reducing their efficiency. Dispersion is also a source of signal degradation in an optical fiber. Transponders, which receive an optical signal from an input fiber and then retransmit the signal on an output fiber, are another device that may increase the distance a signal may be transmitted in an optical communications network. Transponders include both a receiver and a transmitter and are, therefore, a relatively complicated and expensive component. Also, the process of converting the optical signal to an electrical signal, then back to an optical signal, may introduce errors in the signal. Additionally, both in-line amplifiers and transponders require power sources and introduce coupling losses, which lessen their effectiveness.

It is desirable to design transmitters (and transponders) with a long reach (the distance the optical signal may be transmitted without excess degradation to the signal quality). Different sub-components may be used to create transmitters and transponders with different fiber reaches. The output power of the laser source and/or the sensitivity of the receiver may be increased to increase the reach of a transmitter or transponder. The choice of wavelength band for the communication system also plays a role in determining the sub-components to be used in the system. Optical fiber has different loss for different wavelengths, as well as link lengths. For light having a wavelength of 1.3 μm the loss of power in an optical fiber is typically estimated to be 0.5 dB/km. For light at 1.55 μm the corresponding optical loss is typically estimated to be 0.25 dB/km. This may not be the only factor in selecting a wavelength in an optical communications system, though. The choice of wavelength for a particular fiber reach is determined by a total link budget. This link budget is defined by the output power of the transmitter, the total loss through the fiber and connectors, dispersion power penalty, and the receiver sensitivity.

Choices of receivers include; a PIN photodiode receiver (having a sensitivity of −16 dBm), a standard avalanche photodiode (APD) receiver (sensitivity=−21 dBm), and a high end APD receiver (sensitivity=−26 dBm). Although the APD's provide superior sensitivity, they are also significantly more expensive.

In an exemplary optical communication system, a 1.3 μm directly modulated laser (DML) with −4 dBm launch power may be paired up with a PIN photodiode receiver to cover distances up to 12 km. For longer reaches, higher power laser sources, and/or more expensive APD's may be required. Higher power laser sources typically require cooling systems to maintain their performances. Also, higher power laser sources are impractical to operate as DML's. Therefore, external modulators, such as electroabsorption modulators (EAM's) and LiNbO₃ Mach-Zehnder modulators (MZM's), are typically used for higher powered laser sources, but the wavelength sensitivity of these modulators may raise additional issues. Table 1 illustrates transmitter sub-components typically used in existing 10 Gb/s applications.

TABLE 1

| Reach | Laser Source | Modulator |
|---|---|---|
| <600 m | 1.3 μm-uncooled Fabry-Perot laser | None (i.e. DML) |
| <12 km | 1.3 μm-uncooled distributed | None |
| | feedback laser | |
| 20-40 km | 1.55 μm cooled laser | Integrated EAM |
| 40-80 km | 1.55 μm cooled laser | Integrated EAM |
| | 1.55 μm cooled laser | MZM |
| | 1.55 μm cooled laser | Amplified EAM |

ITU SONET specification standards for 1.3 μm optical communications systems have been set to assist in designing these systems as shown in Table 2.

TABLE 2

| | | | Received | Dispersion |
|---|---|---|---|---|
| Standard | Output Power | Reach | Power | penalty |
| OC192, SR-1 | −4 dBm | 12 km | −12 dBm | 1 dB |
| OC192, IR-1 | −1 dBm | 24 km | −13 dBm | 1 dB |
| OC192, LR-1 | 10 dBm | 48 km | −13 dBm | 1 dB |
| OC192, VR-1 | 10 dBm | 72 km | −24 dBm | 1 dB |

Presently sub-components for short and intermediate reach applications (SR-1 and IR-1) are available. A 1.3 μm DML with −4 dBm launch power may be paired up with a PIN photodiode receiver to meet the SR-1 standard. An uncooled 1.3 μm laser integrated with an EAM (EML) or a high performance uncooled 1.3 μm DML paired with a PIN photodiode receiver may meet the IR-1 standard. No viable single transmitter solution is yet available to meet the LR-1 and VR-1 standards. The LR-1 standard may be met with an external SOA and a PIN photodiode receiver and the VR-1 standard may be met with a cooled external SOA and an APD receiver.

In addition to the 1.3 μm specifications, ITU also defines specifications for 1.55 μm systems as shown in Table 3. 1.55 μm operation has less loss in the fiber; however, dispersion in the optical fiber is a greater issue than at 1.3 μm.

TABLE 3

| | | | Received | Dispersion |
|---|---|---|---|---|
| Standard | Output Power | Reach | Power | penalty |
| OC192, SR-2 | −4 dBm | 20 km | −12 dBm | 2 dB |
| OC192, IR-2 | −1 dBm | 40 km | −14 dBm | 2 dB |
| OC192, IR-3 | −1 dBm | 40 km | −13 dBm | 1 dB |
| OC192, LR-2a | −2 dBm | 80 km | −26 dBm | 2 dB |
| OC192, LR-2b | 10 dBm | 80 km | −14 dBm | 2 dB |
| OC192, LR-3 | 10 dBm | 80 km | −13 dBm | 1 dB |
| OC192, VR-2a | 10 dBm | 120 km | −25 dBm | 2 dB |

A 1.55 μm DML with −4 dBm launch power may be paired up with a PIN photodiode receiver to meet the SR-2 standard. A cooled 1.55 μm EML paired with a PIN photodiode receiver may meet the IR-2 and IR-3 standards. The LR-2a standard may be met with cooled 1.55 μm EML, or a laser integrated module configuration (a cooled 1.55 μm laser coupled to an amplified EAM, e.g., a T-Networks LIM™ package), paired with a high performance APD receiver. The LR-2b and LR-3 standards may be met with: a cooled 1.55 μm EML, a laser integrated module, or a cooled 1.55 μm laser coupled to an MZM; an external SOA or erbium doped fiber amplifier (EDFA); and a PIN photodiode receiver. The VR-2a standard may be met with: a cooled 1.55 μm laser coupled to an MZM; an external SOA or EDFA; and a PIN photodiode receiver.

In the short distance market cost, size and power dissipation are important considerations. 10 Gbit Ethernet has similar issues in terms of reach, form factor, and power dissipation tradeoffs. External modulator solutions are not desirable for these markets to get high power. Presently, DML's cannot produce high enough power in uncooled operation at a reasonable reliability to be practical solutions for LR-1 and VR-1 requirements. Cooled solutions are also not desirable in this market owing to the additional power and heat dissipation requirements of these systems. Although DML's may be used at 1.3 μm, they are not used extensively for 10 Gb/s signals at 1.55 μm. DML's have inherently high chirp compared to externally modulated lasers and are, therefore, not suited well for long distance transmission at 1.55 μm. This is because, while the dispersion of the optical fiber is negligible at 1.3 μm, it is relatively high (typically about 17 ps/nm) at 1.55 μm.

Several different form factor standards of transponders and transceivers have been created including: 300 pin MSA (3.5×5″); 300 pin SFF (2×3″); XenPak (36×120 mm); X2/XPAK (76×36 mm); and XFI/XFP (Small, <18 mm wide). Generally, smaller form factor packages are desirable to allow miniaturization of the system, but a smaller factor package may have difficulty dissipating heat generated within it. Each of these standard package form factors is rated to be able to dissipate a certain amount of heat during operation: MSA, 15 W; SFF, 9 W; XenPak, 9 W; X2/XPAK, 4 W; and XFI/XFP; 2-3.5 W.

In a typical cooled laser solution, the laser may have a minimum operating temperature of 25° C., and a desired maximum case temperature of 75° C. Such a cooled laser may need to dissipate close to 2 W of heat. The laser is not the only source of heat within the package that must be dissipated by the package. Electronics within the package and external modulators for long reach transmitters may also generate significant heat. Transponders include additional components that may generate heat. Thus, the XenPak form factor is the smallest desirable form factor package that may be reasonably used in this example. It is, therefore, undesirable to use a cooled laser in any of the smaller form factor solutions.

As described previously, at present there are no uncooled or low power dissipation solutions for reaches greater then 20 km at 1.55 μm and 10 Gb/s. The shorter reach systems typically operate at 1.3 μm. For intermediate reach (40 km) and long reach (80 km) applications, uncooled 1.55 μm EML's may be desirable, but are not available in the market today.

### SUMMARY OF THE INVENTION

An exemplary embodiment of the present invention is a method for substantially maintaining, within a predetermined temperature range, the performance, i.e., output power, extinction ratio, and dispersion penalty, within system limits of an uncooled optical transmitter that includes a laser and an electroabsorption modulator (EAM). α represents the small signal chirp of the device. It is measure at different modulator biases being a measure of the amount of frequency modulation induced by the amplitude modulation of the modulator. Therefore, α(V_{bias}) is a function that can be used to monitor the amount and the signal of the chirp imposed to the modulator by the modulation and the consequences caused to the dispersion penalty. Particularly, the α crossing point (the voltage at which the small signal a curve crosses through zero) may be used as a reference to maintain a constant dispersion penalty in the system. The small signal α crossing points at two temperatures within the predetermined temperature range (or, alternatively, at the lowest temperature in the temperature range) are determined. An EAM bias voltage versus temperature control function is calculated based on the two small signal α crossing points (or, alternatively, the one small signal α crossing point) and the bias voltage of the EAM is adjusted based on this control function, substantially maintaining the dispersion penalty of the transmitter within the predetermined temperature range.

Another exemplary embodiment of the present invention is an uncooled long reach optical transmitter, including an uncooled laser source, an uncooled semiconductor optical amplifier (SOA) optically coupled to the uncooled laser source, and an uncooled EAM optically coupled to the uncooled SOA. The uncooled laser source produces a laser beam, which is amplified by the uncooled SOA. The amplified laser beam is modulated by the uncooled EAM.

An additional exemplary embodiment of the present invention is a method for substantially maintaining, within a predetermined temperature range, the output power of an uncooled optical transmitter, which includes a laser and an SOA. An initial laser bias current and an initial SOA bias current are set. The output power of the uncooled optical transmitter is measured and the SOA bias current is adjusted based on the measure output power to substantially maintain the output power of the uncooled optical transmitter over the predetermined temperature range.

A further exemplary embodiment of the present invention is an uncooled long reach optical transponder, including a PIN photodiode receiver, modulation circuitry electrically coupled to the PIN photodiode receiver, an uncooled laser source, an uncooled SOA optically coupled to the uncooled laser source, and an uncooled EAM optically coupled to the SOA and electrically coupled to the modulation circuitry. The uncooled laser source produces a laser beam, which is amplified by the uncooled SOA. The modulation circuitry is adapted to provide a modulation signal responsive to an optical signal incident on the PIN photodiode receiver. The uncooled EAM modulates the amplified laser beam in response to the modulation signal to form an output optical signal of the uncooled long reach optical transponder.

Yet another exemplary embodiment of the present invention is a method for improving the reliability of an uncooled long reach optical transmitter operating substantially at a predetermined output power. The uncooled long reach optical transmitter in this exemplary method includes a laser and an SOA. The laser is operated at reduced bias current injections to produce a reduced power laser beam, thereby improving the laser reliability. The SOA bias current is controlled so that the SOA amplifies the reduced power laser beam to substantially maintain the predetermined output power. The SOA is sufficiently long to provide this amplification, while maintaining a reduced current density within the SOA, thereby improving the SOA reliability.

Still another exemplary embodiment of the present invention is a method for manufacturing a monolithic laser integrated module for use in an uncooled long reach optical transmitter. A substrate base having a substrate base index of refraction is provided. A grating layer is formed over the substrate base. The grating layer has a grating index of refraction, which is different from the substrate base index of refraction. The grating layer is defined and etched to form a grating base section having a grating period. A top substrate layer is formed over the substrate base and the grating base sections. The top substrate layer has a substrate index of refraction, which is different from the grating index of refraction. A quantum well layer is formed on the top surface of top substrate layer. The quantum well layer, which has a waveguide index of refraction different from the substrate index of refraction, includes a plurality of sub-layers forming a quantum well structure. Each of these sub-layers includes a waveguide material. A semiconductor layer is formed on the quantum well layer. The semiconductor layer has a semiconductor layer index of refraction different from the waveguide index of refraction. The quantum well layer and the semiconductor layer are defined and etched to form a distributed feedback laser section, an SOA section, and an EAM section in the quantum well layer. A distributed feedback laser electrode, an SOA electrode, and an EAM electrode are deposited on the semiconductor layer in positions corresponding to portions of the distributed feedback laser section, the SOA section, and the EAM section of the quantum well layer, respectively.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawing are the following figures:

FIG. 1 is a graph illustrating cumulative failure rates of exemplary semiconductor lasers.

FIG. 2 is a flow chart illustrating an exemplary method of operating an exemplary uncooled long reach optical transmitter according to the present invention to improve reliability.

FIG. 3A is a block diagram of an exemplary uncooled long reach optical transmitter according to the present invention.

FIG. 3B is a block diagram of another exemplary uncooled long reach optical transmitter according to the present invention.

FIG. 3C is a block diagram of a further exemplary uncooled long reach optical transmitter according to the present invention.

FIG. 4 is a side plan drawing of an exemplary monolithic uncooled long reach optical transmitter according to the present invention.

FIG. 5 is a flow chart illustrating an exemplary method of manufacture for the exemplary monolithic uncooled long reach optical transmitter of FIG. 4 according to the present invention.

FIGS. 6A, 6B, and 6C are side plan drawings of the exemplary monolithic uncooled long reach optical transmitter of FIG. 4 during manufacture according the exemplary method of FIG. 5.

FIGS. 7A and 7B are graphs illustrating output power flattening of an exemplary uncooled long reach optical transmitter according to the present invention.

FIG. 8 is a flow chart illustrating an exemplary method of flattening the output power an exemplary uncooled long reach optical transmitter according to the present invention.

FIG. 9 is a graph illustrating the effect of the EAM bias of an exemplary uncooled long reach optical transmitter on output power of the exemplary transmitter.

FIG. 10 is a graph illustrating the effect of the temperature of an exemplary uncooled long reach optical transmitter on the α crossing point of the exemplary transmitter.

FIG. 11 is a flow chart illustrating an exemplary method of controlling the dispersion penalty an exemplary uncooled long reach optical transmitter according to the present invention.

### DETAILED DESCRIPTION OF THE INVENTION

One exemplary embodiment of the present invention is a transmitter, or transponder, capable of 80 km 10 Gb/s performance with 0 dBm-modulated power in an uncooled application, and able to be packaged in a small form factor package, such as SFF, XenPak, X2/XPAK, or XFI/XFP. This device may enable long reach, small form factor solutions for optical communication systems, providing small form factor transmitters and transponders for OC192 standard IR-2, IR-3, LR-2a, LR-2b, and LR-3 applications.

Another exemplary embodiment of the present invention is a design of a transmitter, or transponder, which is small, and operates at a wavelength of 1.3 μm. This exemplary design can enable transmitters and transponders for LR-1, and VR-1 links in the smaller form factor packages where power dissipation is a significant issue and direct modulated lasers cannot achieve the desired output power.

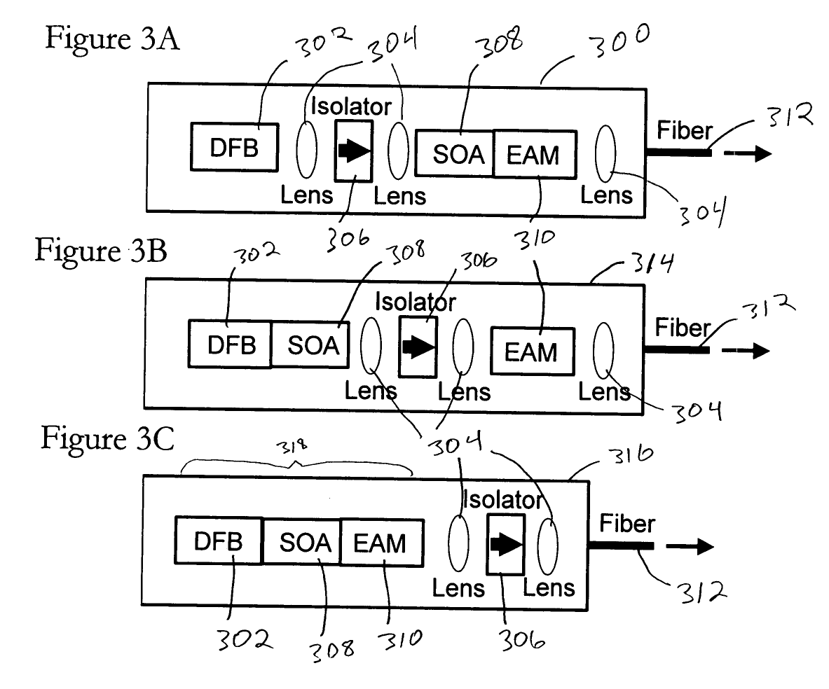

As described above, it is desirable to design a long reach transmitter, which may be operated without external cooling to allow smaller form factor packaging. In an exemplary embodiment of the invention, this goal may be achieved using a laser integrated module. Exemplary laser integrated module configuration 300, shown in FIG. 3A, monolithically integrates semiconductor optical amplifier (SOA) 308 and electroabsorption modulator (EAM) 310 to form an amplified EAM (e.g., a T-Networks EAMP™), which may be used to boost the output power of the transmitter without increasing the output power of the laser. Separate SOA and EAM sub-components may also be used in this exemplary embodiment, but may introduce additional coupling losses. Laser integrated module 300 may be created either for 1.3 μm or 1.55 μm operation, as may alternative exemplary laser integrated module configuration in exemplary transmitters 314 and 316 shown in FIGS. 3B and 3C, respectively. Several issues, which are important to achieving uncooled operation in transmitters (or transponders), may be addressed by use of these exemplary configurations, such as reliability, performance over a temperature range, and control over temperature of the device.

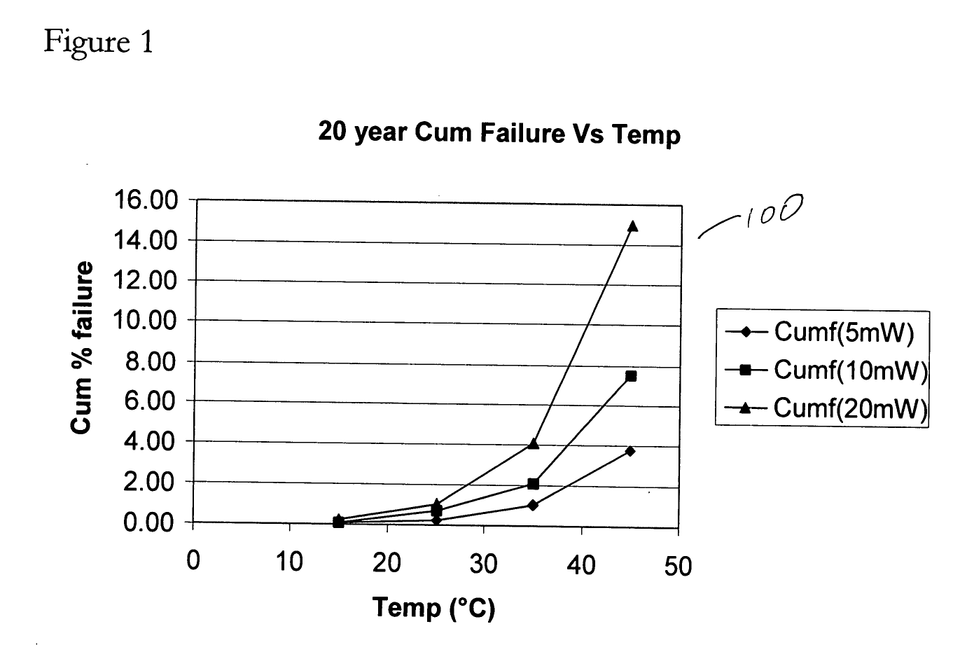

Desirable to proper operation of any communications systems is reliability. In an uncooled optical communications transmitter application, reliability is an increased concern. Performance of many electro-optical devices, such as lasers, degrades over time and this degradation is generally accelerated at higher temperatures. However, the reliability of semiconductor lasers may be significantly increased as the laser power is reduced, as well. Graph 100 in FIG. 1 illustrates typical laser reliability characteristics for an exemplary semiconductor laser operated at several output power levels. As illustrated in graph 100 both operating temperature and output power are significant to the cumulative failure rate of an exemplary semiconductor laser.

If the overall reliability of the laser were to be improved through improved design or fabrication methods, then exemplary transmitters and transponders, which may be operated at a constant high temperature, may result. The thermoelectric cooler (TEC) would then only need to provide minimal cooling to such a laser source, possibly decreasing the TEC power demands to <0.5 W of heat dissipation. This may provide a viable solution for transmitters utilizing some of the larger form factor packages, but the TEC may still be too large for the ultra small form factor solutions. Therefore, for ultra small form factor packages, uncooled laser operation is desirable, even though uncooled operation leads to issues of stable operation over a temperature range and device control, as well as reliability.

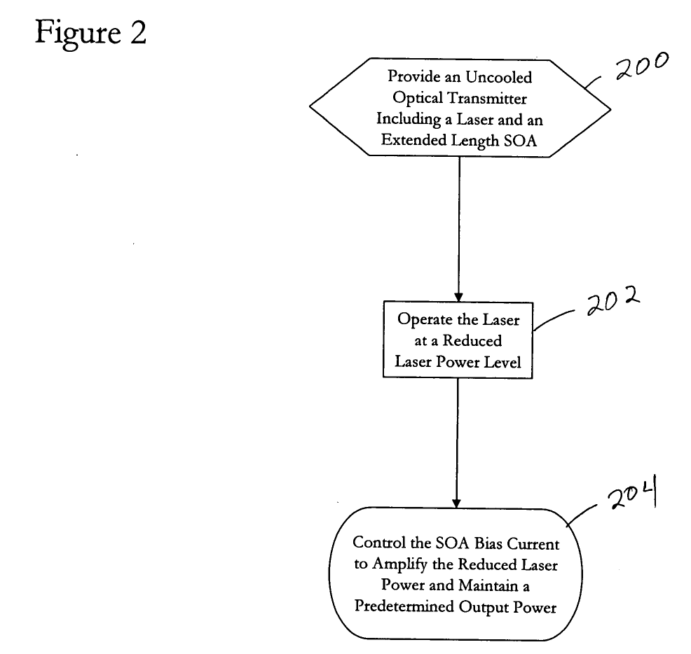

The reliability parameters for a 10 Gb Ethernet system are preferably at least a median time to failure (MTTF) of 15 years at 50° C. The reliability requirement for SONET/SDH is typically 1-3% cumulative failure rate (CFR) over 10 years at a chip temperature of 50° C. However, as shown in FIG. 1, the reliability of semiconductor lasers dramatically increases as the laser power is reduced. This provides an exemplary method, illustrated in the flowchart of FIG. 2, to achieve adequate reliability during uncooled operation of a long reach optical transmitter, or transponder, at a predetermined output power.

An uncooled long reach optical transmitter including a laser and a SOA is provided, step 200. An external modulator is also desirably included in the uncooled long reach optical transmitter, as well as, an optical isolator to desirably reduce feedback into the laser. FIGS. 3A-C illustrate possible exemplary configurations of these sub-components. Lenses 304 may also be included to improve optical coupling between the subcomponents of the uncooled long reach optical transmitter, and/or output fiber 312. Although FIGS. 3A-C show lasers 302 as distributed feedback (DFB) lasers and external modulators 310 as an EAM's, it is contemplated that other semiconductor lasers, such as Fabry-Perot and distributed Bragg reflector (DBR) lasers, and external modulators, such as Mach-Zehnder modulators (MZM), may alternatively be used in various embodiments of the present invention.

The laser is operated at a reduced output power level, step 202. As shown in FIG. 1, using this reduced output power level improves the laser reliability. In a transmitter without an integrated amplifier, allowed reduction of the output power of the laser is minimal for long reach applications due to the maximum receiver sensitivity available, not to mention coupling losses. External optical amplifiers may boost the signal to allow some additional laser power reduction, but these external amplifiers add cost and complicity of transmission design and may add chirp to the signal, increasing the dispersion penalty. Amplification of the laser beam by an SOA situated between the laser and the modulator is, therefore, desirable, to allow significant reduction of the laser output power. The amount of power reduction of the laser and the amplification of the SOA desired may be determined by examining a power budget for the desired output power of exemplary transmitter. An example of the power budgets for the exemplary laser integrated module configuration of FIG. 3A, in cooled and uncooled operation is shown in Table 4.

TABLE 4

| | Laser | Coupling | SOA | EAM | Coupling | Power |
|---|---|---|---|---|---|---|
| | Power | Loss | Gain | Loss | Loss | Output |
| Cooled | 13 dBm | −4 dBm | 4 dB | −4 dB | −2 dB | 7 dBm |
| Uncooled | 3 dBm | −6 dBm | 13 dB | −4 dB | −3 dB | 3 dBm |

The coupling losses are estimated to increase in the uncooled example due to the large range of thermal expansion and larger peak wavelength variation anticipated during uncooled operation over a varying temperature environment. These temperature induced variations may lead to difficulties in optimizing optical coupling between the subcomponents of the exemplary transmitter. To reduce the temperature range for operation, high forced operating temperature of the laser may be possible to improve the coupling losses without adding significantly to the heat that must be dissipated by the package. A resistive heating element may even be used, saving space and cost as compared to a thermoelectric cooler, but the time constants associated with temperature settling using this means may be undesirably long for some applications.

It is also noted that at a constant bias current the output intensity of the laser may vary significantly. To overcome this problem, the SOA bias current may be controlled to variably amplify the reduced output power of the laser and maintain a substantially constant output power level, step 304. This allows the exemplary uncooled long reach optical transmitter to maintain a fixed output intensity across a wide temperature range, at least 80° C.

High temperatures also reduce the reliability of SOA's. Another important factor in the reliability of an SOA is the current density in its active layer. The higher the operational current density the SOA, the higher the cumulative failure rate of the SOA, similar to the effect of the output power on laser reliability. Therefore, it is desirable to operate an SOA, particularly one operated at elevated temperatures, with the lowest possible current density. In the present exemplary embodiment, the SOA is desirably sufficiently long to provide the desired amplification, while maintaining a reduced current density within the SOA, thereby improving the SOA reliability.

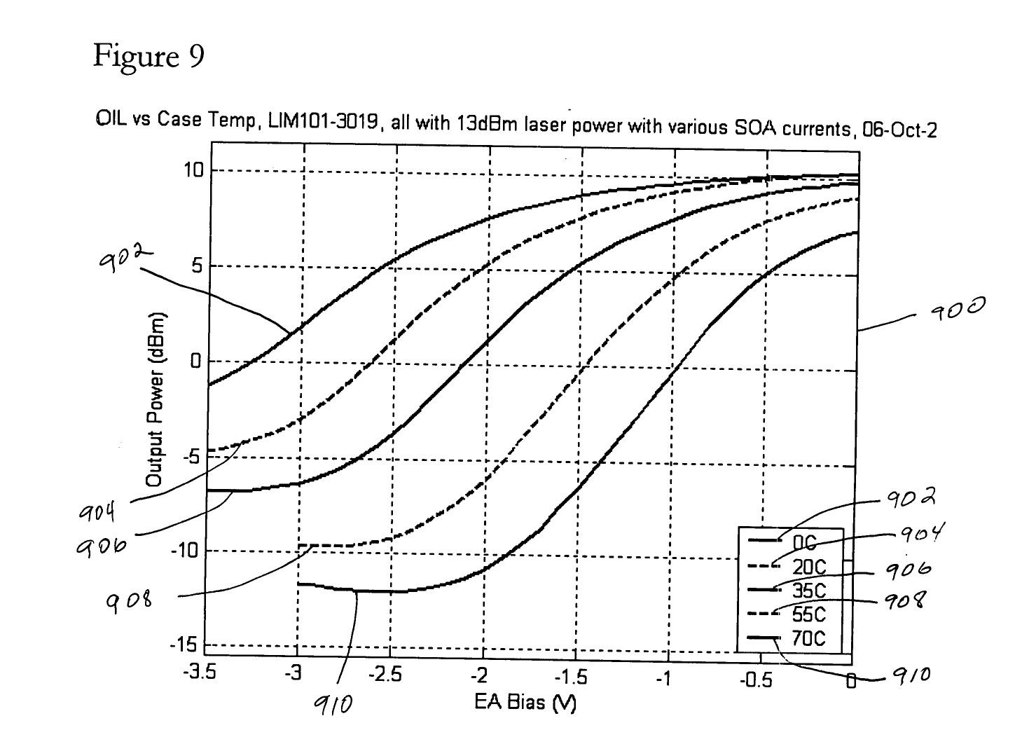

It is also noted that the dispersion penalty of the exemplary transmitter may be affected by the chirp generated in the EAM, which may also be sensitive to the operating temperature of the transmitter. This dispersion penalty may be substantially controlled by adjusting the EAM bias voltage, as discussed below with reference to FIGS. 9, 10 and 11.

By improving the reliability of both the laser and SOA the present method may significantly improve the overall reliability of an exemplary uncooled long reach transmitter, or transponder. This improved reliability is an important step toward desirably designing a long reach optical transmitter capable of being mounted in a small form factor package.

An exemplary approach to an uncooled long reach transmitter design is the combination of an SOA and a laser to achieve high output power with increased reliability, the method of FIG. 2. Exemplary laser integrated module 300, which incorporates laser 302, isolator 306, SOA 308, and EAM 310 all integrated in a small single transmitter, as shown in FIG. 3A, may be used. In this embodiment, SOA 308 and EAM 310 may be formed monolithically or may be separate subcomponents. If it is a separate subcomponent, the external modulator may be an MZM instead of an EAM.

Alternatively, DFB, or DBR, laser 300 and SOA 308 may be formed monolithically with separate optical isolator 306 and EAM 310, exemplary uncooled long reach transmitter 314 of FIG. 3B, or the laser 302, SOA 308, and EAM 310 may all be formed as one monolithic structure, exemplary uncooled long reach transmitter 316 of FIG. 3B. In exemplary uncooled long reach transmitter 316, it is desirable for optical isolator 306 to follow the monolithic Laser/SOA/EAM structure to reduce feedback from further optics within the transmitter or transponder package or from output fiber 312, as shown in FIG. 3C.

The SOA reliability is dependent primarily on current density within the SOA. By making the SOA longer, higher gain may be achieved while maintaining operation at a constant current density, and reliability. Thus, the DFB laser may be operated at a lower power and the SOA gain may be increased to compensate, thereby maintaining reasonably high output power for the transmitter, or transponder, without sacrificing reliability. In this way, increased reliability in an uncooled transmitter or transponder may be achieved by operating the laser and the SOA at low-current density.

Also of importance for uncooled applications is substantially stable performance over a temperature range, as uncooled systems may be more susceptible to changes in temperature during operation than cooled systems. The addition of the SOA to the exemplary transmitter enables an exemplary configuration to utilize independent control of the SOA gain by adjusting the SOA current. Increasing the drive current to the laser to maintain output power as temperature increases may undesirably affect the wavelength, linewidth, and noise of the laser output, as well as its reliability. Therefore, adjusting the SOA gain may provide a more desirable method to flatten the output power of the transmitter over a temperature range.

An optical power detector may be optically coupled to the uncooled EAM to monitor the average output power of the modulated laser beam. Evanescent coupling or a small optical fiber pick off may be used to minimize the power loss due to this power monitoring. Feedback from the optical power detector may be used to control the bias current of the SOA to maintain a substantially constant average output power level.

A temperature insensitive wavelength detector, such as that described in U.S. patent application Ser. No. 10/337,443, INTEGRATED, TEMPERATURE INSENSITIVE WAVELENGTH LOCKER FOR USE IN LASER PACKAGES, may also be optically coupled to the uncooled EAM to monitor output wavelength of the modulated laser beam. This may allow control of the laser bias current to reduce wavelength variation of the exemplary uncooled transmitter.

A resistive heating element may also be coupled to exemplary transmitters 300, 314, and 316 to allow limited temperature control at elevated temperatures. A temperature sensor may also be desirable in this embodiment. Alternatively, in the case of a transmitter which includes a temperature insensitive wavelength detector, the heater may be used, alone or in conjunction with the laser bias current, to reduce wavelength variation of the exemplary high temperature transmitter.

An uncooled long reach optical transponder may be formed by including a PIN photodiode receiver and modulation circuitry inside the package. The modulation circuitry is desirably adapted to provide a modulation signal which is responsive to an optical signal incident on the PIN photodiode receiver. When generating the modulation signal, the electrical signal from the PIN photodiode receiver may be filtered to remove noise and/or amplified by the modulation circuitry. This modulation signal is used to drive EAM 310 modulating the amplified laser beam to form the output optical signal of the uncooled long reach optical transponder.

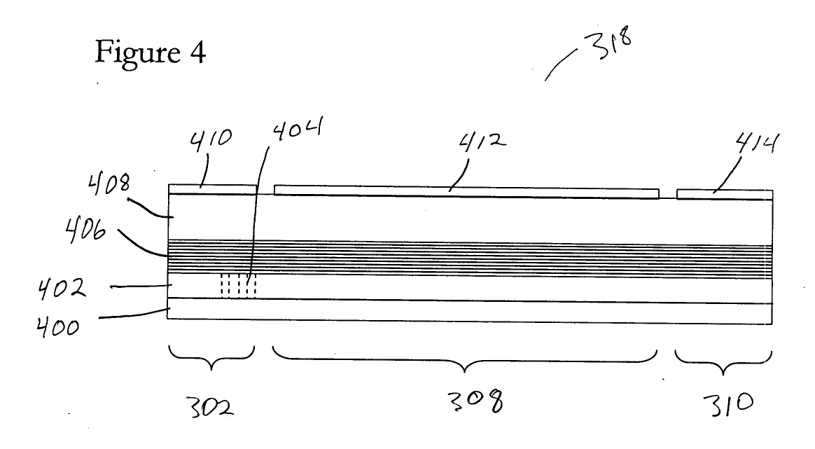

Monolithic laser integrated module 318 in exemplary uncooled long reach transmitter 316 of FIG. 3C may have reduced coupling losses, allowing even lower power operation of DFB, or DBR, laser 302 and/or SOA 308. The exemplary division between SOA gain and DFB laser power enables high temperature, high reliability operation for uncooled LR applications. FIG. 4 shows a side plan drawing of this exemplary laser integrated module configuration. Monolithic laser integrated module 318 includes a substrate formed of substrate base 400 and top substrate layer 402, waveguide layer 406, and semiconductor layer 408. Laser electrode 410, SOA electrode 412, and EAM electrode 414 define laser section 302, SOA section 308, and EAM section 310 of monolithic laser integrated module 318, respectively. The substrate includes grating section 404 located in laser section 302. Grating section 404 may extend from the output edge of laser section 302 partially across the section, as shown, or may extend the length of the section.

Monolithic laser integrated module 318 is desirably grown by low-pressure metal-organic chemical vapor deposition of III/V materials. To enable longer wavelength operation, laser section 302 and SOA 308 may be grown with an enhanced deposition rate by selective area growth (SAG). The epitaxial structure for monolithic laser integrated module 318 consists of a separated confinement (SCL) design with an active region employing quantum wells formed of layers of III/V materials, which may be compressively strained. Graded layers of III/V material are desirably employed between the quantum wells and cladding layers to minimize carrier accumulation and power saturation. The quantum wells and graded layers may desirably be formed of InGaAlAs and the cladding layers of InP. Exemplary cladding layer compositions and doping profiles were reported in LOW INSERTION LOSS AND LOW DISPERSION PENALTY InGaAsP QUANTUM WELL HIGH SPEED ELECTROABSORPTION MODULATOR FOR 40 GB/S VERY SHORT REACH, LONG REACH AND LONG-HAUL APPLICATIONS, by W. Choi, et al. in IEEE Journal of Lightwave Technology, 2002, vol. 20, pp. 2052-2056. After the waveguide formation, the sample may be planarized with polyimide (not shown) to reduce a metal pad capacitance and standard p and n contacts are deposited by electron beam deposition. Antireflection coatings may be desirably deposited on the output facet after cleaving.

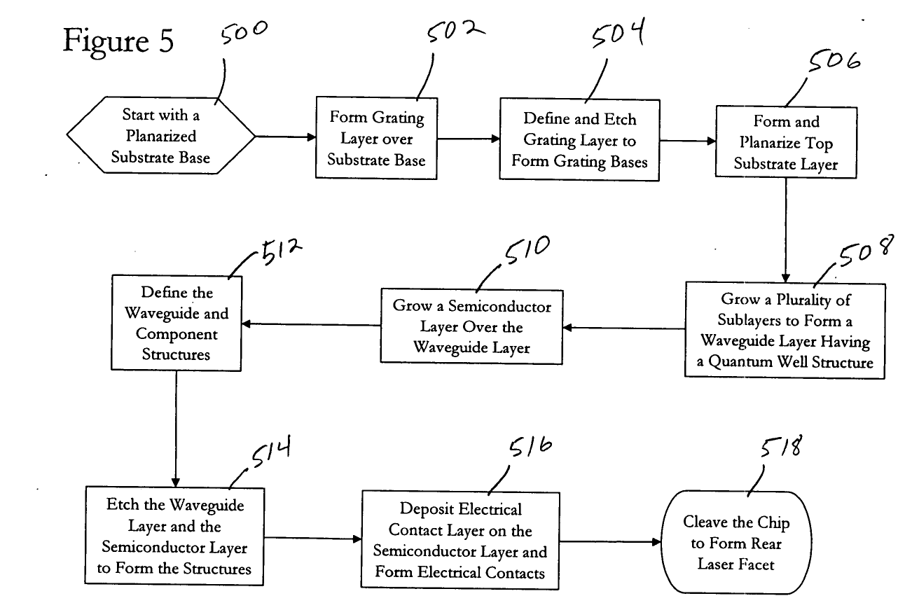

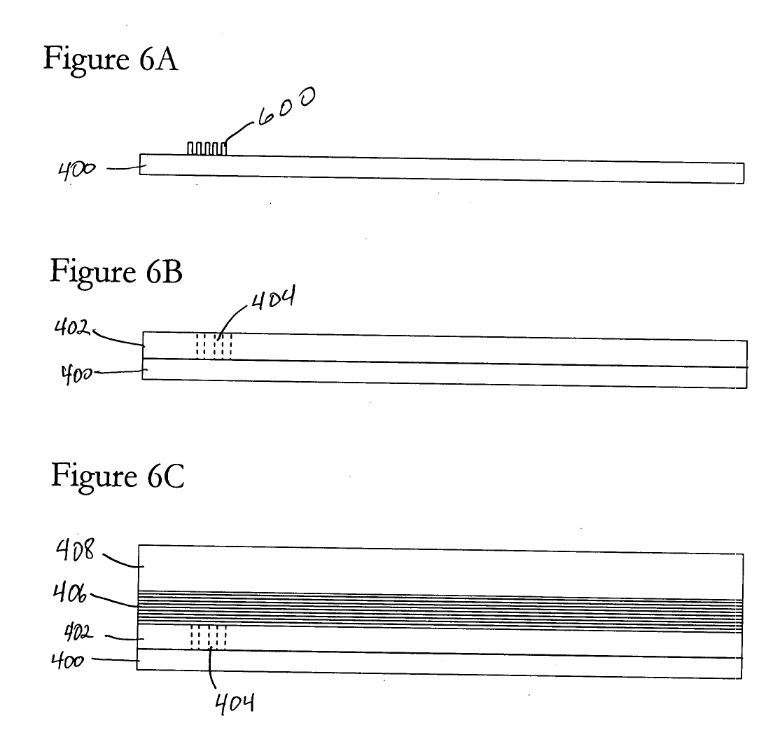

FIG. 5 is a flowchart describing an exemplary method of manufacture for producing exemplary monolithic laser integrated module 318 from FIG. 4. FIGS. 6A, 6B, and 6C illustrate various steps of this exemplary fabrication process.

The process begins with a planarized substrate base, step 500. Substrate base 400 is preferably formed of a III/V semiconductor, such as InP, GaAs, or InGaAsP. The substrate base may also be formed of multiple layers such as GaAs grown on silicon or alumina. A grating layer is formed over substrate base 400, step 502. Metal organic chemical vapor deposition (MOCVD) is one exemplary method that may be used for deposition of this grating layer, but other epitaxial deposition techniques may also be employed, such as molecular beam epitaxy (MBE), chemical vapor deposition (CVD), and chemical beam epitaxy (CBE). The grating layer desirably has a sufficiently larger refractive index than substrate base 400 to provide the scattering necessary for the optical grating section of DFB, or DBR, laser section 302 of the exemplary laser integrated module. This grating layer is also desirably formed of a material of the same family as substrate base 400. For example, an InP grating layer may desirably be formed on an InGaAsP substrate base.

A grating portion of the grating layer is defined and etched to form grating base 600 with a series of parallel lines, step 504. These parallel lines may desirably be formed using a photolithographic technique, such as phase masking or e-beam writing, and a wet chemical etch. Alternatively, a dry etch technique, such as reactive ion etching, may be used. Grating base 600 is formed with a grating period selected to provide the desired feedback for laser section 302. FIG. 6A depicts the exemplary monolithic laser integrated module at this stage of manufacture.

Top substrate layer 402 is formed over etched grating base 600 to form optical grating 404 and this layer is then planarized, step 506. MOCVD or another epitaxial deposition technique may be employed. It may be desirable for the same deposition technique to be used to form all of the semiconductor layers in this exemplary method. Top substrate layer 402 desirably has a sufficiently smaller refractive index than grating base 600, and preferably similar to substrate base 400, to provide the scattering necessary for optical grating 404 of exemplary monolithic laser integrated module 318. FIG. 6B illustrates the in-process exemplary monolithic laser integrated module at this point in its manufacture.

Substrate base 400 and top substrate layer 402, shown in FIG. 6B, may function as both a cladding layer to assist in containment of the beam in the device and as the N layer of the P-I-N quantum well structure. (Although this description assumes that the substrate is the N side of the P-I-N structure, one skilled in the art will understand that the substrate could be the P side with the semiconductor layer 402 formed of N-type material instead.) Top substrate layer 402 also functions as the low refractive index portion of optical grating 404.

An alternative exemplary method may be employed to form optical grating 404. In this alternative method, a grating portion of substrate base 400 is defined and etched to form a grating base with a series of parallel lines. The grating layer is formed over these etched grating bases to form optical grating 404, using MOCVD or another epitaxial deposition technique. This layer is then planarized. No top substrate layer is necessary. Substrate base 400 also functions as the low refractive index portion of optical grating 404, in this alternative embodiment.

Once optical grating 404 is formed, a plurality of sub-layers making up quantum well layer 406 are grown, step 508. MOCVD or another epitaxial deposition technique may be employed. The quantum wells and barriers may desirably be composed of InₓAl_{y}Ga₍₁₋ₓ₎As_{(1-y)} materials, as well as InₓGa₍₁₋ₓ₎As_{y}P_{(1-y)} and InₓGa₍₁₋ₓ₎As materials. Specific selections of x and y depend on the desired bandgap and strain, if any, desired. These sub-layers may also be formed by other permutations of alloys formed from III/V elements. The quantum wells and barriers of quantum well layer 406 desirably have a sufficiently larger refractive index than the top substrate layer 402 so that the quantum wells and barriers may act as a waveguide. In an exemplary embodiment the quantum well layer may desirably include strained InGaAlAs sub-layers and/or graded InGaAlAs sub-layers.

It is noted that one property of quantum well structures, which may be desirably exploited in this exemplary method, is that as the thickness of the quantum well increases the band gap or energy of the absorption peak decreases. Bias voltages applied to quantum well structures may also shift the band gap of the structure. By using selective area growth it is possible to grow a single multi-layer quantum well structure of varying thickness, and thus having a varying zero bias band gap energy. This may desirably allow tuning of the biased band gaps of the section of exemplary monolithic laser integrated module 318 to improve the efficiency of the monolithically integrated sub-components.

To include this alternative exemplary feature step 504 includes the formation of at least one patterned growth retarding mask on a laser area and an SOA area of the top surface of the top substrate layer. Materials which retard growth of III/V materials, such as SiN or SiO₂, make up the growth retarding mask(s). The growth retarding mask may be formed and patterned using any standard techniques known in the semiconductor industry. The patterned growth retarding mask(s) may be formed as two rectangular regions with a channel between disposed along longitudinal axis of the monolithic laser integrated module in laser section 302 and SOA section 308. For an exemplary monolithic laser integrated module with a 2 μm wide waveguide, a 15 to 20 μm channel is desirable to provide substantial flatness of the layers in a transverse direction. Depending on the profile desired for the waveguide layer, other patterns, such as paired trapezoids or triangles, may be used. A larger number of regions may also be used.

When the plurality of sub-layers making up the waveguide layer are grown, the growth rate near the growth-retarding regions is enhanced owing to gas phase diffusion and surface diffusion of the reactants in the MOCVD reactor away from the growth-retarding regions. The quantum wells layers thus deposited are made thicker in laser section 302 and SOA section 308 than in EAM section 310 of the device owing to the growth-retarding masks.

Next semiconductor layer 408 is formed over waveguide layer 406, step 510. This step of the fabrication process is illustrated in FIG. 6C. Preferably, semiconductor layer 408 is formed using the same method as the quantum well layer 408. The semiconductor layer desirably has a refractive index lower than quantum well layer 406, preferably similar to that of top substrate layer 402, to ensure light containment. Additionally, the semiconductor layer may be formed of a P type material, for example, P-type InP or GaAs. Also, semiconductor layer 408 may be formed in multiple sub-layers.

Note that if the thicknesses of the sub-layers of quantum well layer 406 are varied using selective area growth, then the thickness of semiconductor layer 402 may be varied as well, if the growth retarding masks are not removed before step 510.

Step 512 defines the waveguide and component structure of exemplary monolithic laser integrated module, for example, by selectively forming photoresist over the desired waveguide and component structure. This structure includes a mesa waveguide structure with a laser section, an SOA section, and an EAM section arranged longitudinally along the waveguide.

Next quantum well layer 406 and cladding layer 408 are etched to form this structure, step 514. Steps 512 and 514 may be performed using standard wet or dry etch techniques. Although steps 512 and 514 are shown following step 510 in FIG. 5, it is contemplated that steps 512 and 514 could alternatively take place between steps 508 and 510. In this case semiconductor layer 408 would be grown to encase quantum well waveguide layer 406.

Once the waveguide and component structure is formed, p-type ohmic contacts are deposited on semiconductor layer 408 to form laser electrode 410, SOA electrode 412, and EAM electrode 414, step 516, as shown in FIG. 4. These electrodes may be formed of a conductive material, such as aluminum, gold, silver, copper, nickel, titanium, tungsten, platinum, germanium, polyaniline, polysilicon or a combination of these materials. Alternatively, step 516 could take place before the structure is formed, steps 512 and 514.

The device may be cleaved, step 518, to form the rear facet of the DFB, or DBR, laser and the output port of the exemplary monolithic laser integrated module 318. Steps 516 and 518 may be carried out by any of a number of standard semiconductor fabrication techniques known to those skilled in the art. The output port may be anti-reflection coated to reduce losses and reflections. Alternatively the output port may be formed using a low-loss optical coupling technique such as a buried facet. The cleaved rear facet of the laser functions as a reflector for the laser. The relatively high index of refraction of the waveguide materials desirably leads to approximately 30% reflectivity for this surface. This reflectivity may be increased by coating this surface with several dielectric layers to form a dielectric mirror and/or metallization layer, if desired.

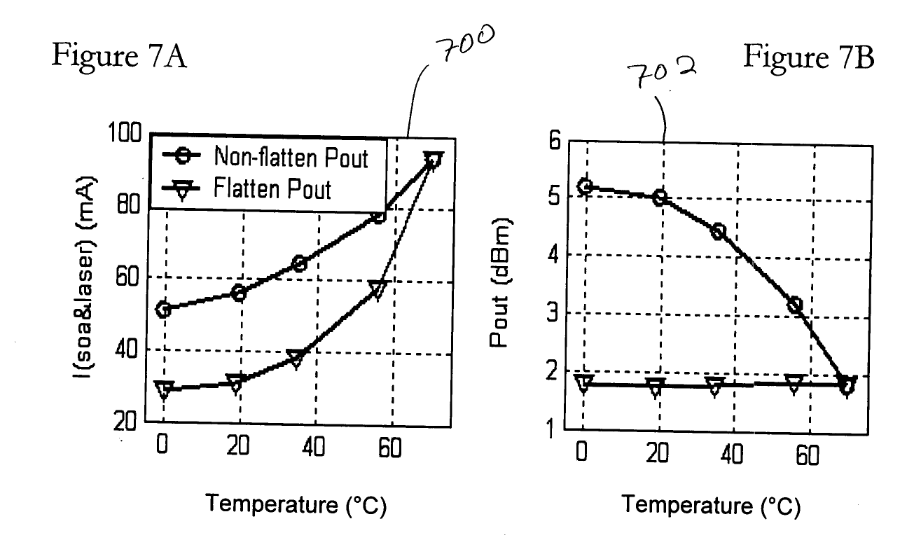

As noted above, output power flatness of an exemplary uncooled long reach transmitter may be achieved by operating the integrated SOA as a variable amplifier. A control circuit, such as a micro-controller or a digital signal processor, may be used to monitor a temperature sensor, such as a thermistor mounted in the package, and determine the desired current to be applied to the SOA from a look-up table based on the temperature sensor reading. The SOA current may then be adjusted to maintain a constant optical output power. Thus, using this exemplary laser integrated module architecture in uncooled applications may allow for use of ultra-small form factor packaging. Alternatively, the output power may be directly monitored and the bias current of the SOA adjusted accordingly. FIGS. 7A and 7B illustrate how division of drive current between the DFB laser and the SOA in the exemplary laser integrated module configuration may allow for a constant output power (Pₒᵤₜ) over a large temperature range.

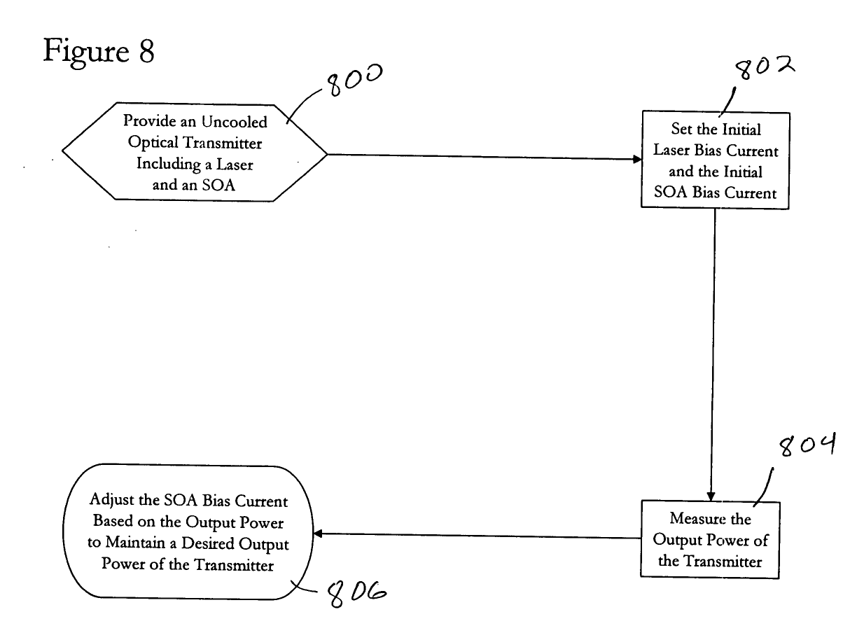

FIG. 8 is a flowchart illustrating an exemplary method for substantially maintaining, within a predetermined temperature range, the output power of an uncooled optical transmitter. The uncooled optical transmitter, which includes a laser and an SOA, is provided, step 800. Initial laser and SOA bias currents are set, step 802. The initial laser bias current is selected such that the output power of the laser, at an anticipated operating temperature, is desirably low, but far enough above threshold for stable operation. The initial SOA bias current is the bias current estimated to provide the desired transmitter output power at the anticipated operating temperature.

The output power of the uncooled optical transmitter is measured, step 804, desirably using evanescent coupling or a low loss optical pickoff. It is contemplated that the output wavelength of the uncooled optical transmitter may also be measured at this step. The laser bias current may be adjusted to maintain a substantially constant output wavelength for the uncooled optical transmitter. The SOA bias current may be dynamically adjusted based on the measured output power of the uncooled optical transmitter to maintain a substantially constant output power level, step 806.

By controlling the bias point of an exemplary uncooled optical transmitter, the dispersion penalty over temperature through 40 or 80 km of fiber may also be controlled. Controlling the dispersion penalty over temperature is desirable for achieving uncooled long reach operation and may desirably be accomplished in the exemplary laser integrated module architectures, such as those shown in FIGS. 3A and 3B. Laser 302 may be isolated from EAM 310, which helps prevent adiabatic chirp, while high power and increased reliability levels may be achieved with via SOA 308. The combination of these two design features in exemplary uncooled long range transmitters 300 and 314 of FIGS. 3A and 3B enable a solution to both the issue of adiabatic chirp and the reliability issues of uncooled long range transmitters.

Although exemplary monolithic laser integrated module 318 of FIGS. 3C and 4 does not provide complete isolation between laser 302 and EAM 310, the decrease in coupling losses derived from monolithically forming the laser integrated module may prove to outweigh any resulting adiabatic chirp. Additionally, the EAM may be isolated to a substantial degree by including an extended section of waveguide between SOA 308 and EAM 310. This section of waveguide may be formed of the same structure as the three active devices in exemplary monolithic laser integrated module 318, but without electrodes connected to provide a bias. Alternatively, the waveguide section could include electrodes coupled to a common voltage, preferably ground, to guard against leakage current from SOA 308 and EAM 310. EML's cannot achieve the output power over temperature and the adiabatic chirp cannot be controlled over such a wide wavelength range.

The optical extinction curves of an EAM change as a function of temperature. Graph 900 of FIG. 9 illustrates loss as a function of voltage for an exemplary EAM. Curves 902, 904, 906, 908, and 910 represent measurements of the exemplary EAM at chip temperatures of 0° C., 20° C., 35° C., 55° C., and 70° C., respectively. Signal modulation introduces a 2-3 dB reduction in average signal power. EAM's are often formed to include a quantum well structure for electroabsorption, which is sensitive to external conditions such as temperature and electric fields. Graph 900 shows that adjusting the EAM bias voltage allows the absorption characteristics of the EAM to be tuned. The absorption peak and absorption spectrum shape of the quantum well structure may also depend on the composition and thickness of the sub-layers which make up the quantum well structure. The sub-layers of the quantum well structure may be designed so that the EAM operates most efficiently under certain external conditions. The exemplary EAM characterized in FIG. 9 is designed to operate with low loss and low bias voltage in the temperature range of 0-50° C. By properly designing an EAM, optical signal modulation may be accomplished with minimal loss and relatively low EAM bias voltage at higher temperature ranges.

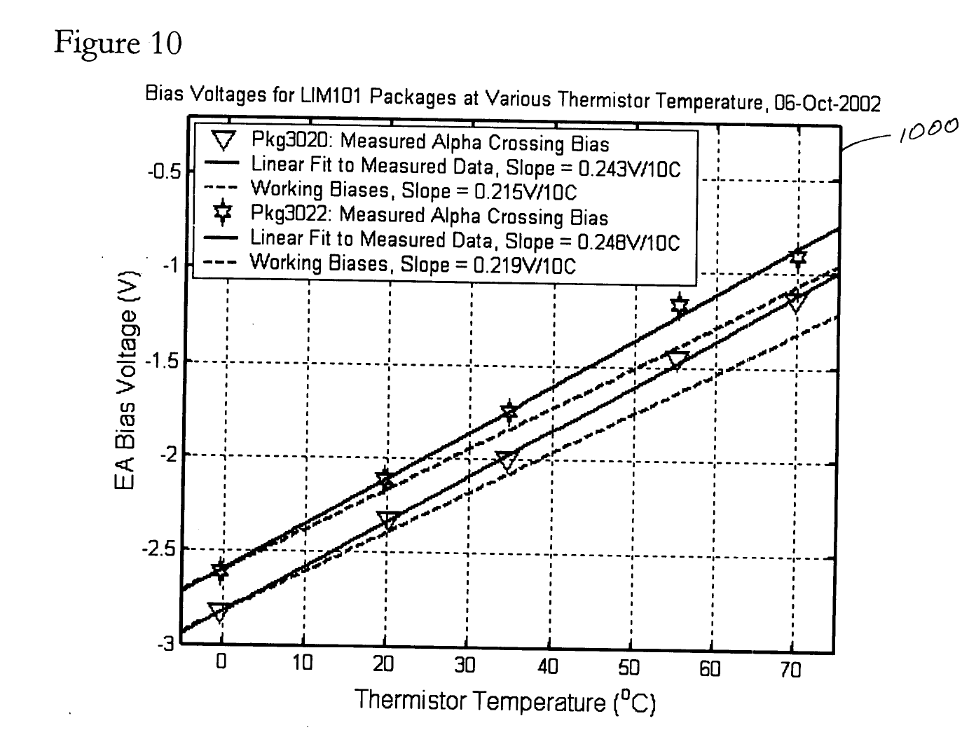

The dispersion penalty of an EAM is based on the amount of chirp introduced during modulation. It is desirable for the EAM to be able to operate with a similar dispersion penalty over a temperature range. An algorithm may be used to change the voltage applied to the EAM as a function of temperature to maintain a similar dispersion penalty for the signal. FIG. 10 illustrates an exemplary functional relationship that may be used to determine the desired EAM bias voltage versus temperature algorithm.

In exemplary graph 1000, α represents the small signal chirp of the device. This is a measure of the amount of frequency modulation induced in the output by small amplitude modulations from the EAM for different voltage biases. It is desirable for a to be maintained at a substantially constant value over desired temperature range of operation. The desired value of α is chosen based on the fiber link length. These desired α values are usually close to zero and are negative in many cases. For example, an effective α of −0.6 may be desirable for data transmission over an 80 km SMF fiber to maintain a dispersion penalty of less than 2 dB.

The α crossing point (V_{cr}) (the voltage at which the small signal α curve crosses through zero) can be used as a reference to maintain a constant dispersion penalty in the system. The solid lines in graph 1000 represent linear fits to the measured α crossing points of two exemplary T-Networks LIM™101 transmitter packages. As shown in this figure, the linearity of the relationship of V_{cr} to the operating temperature is high within at least a range of 70° C. Also, although the values of V_{cr} may vary significantly at a given temperature between EAM's, as shown in graph 1000, the slope of the V_{cr} versus temperature relationship remains virtually constant for EAM's formed from the same material system.

Desirably, the EAM may be designed so that the desired working bias voltage may be substantially equal to V_{cr} near the lower end of the desired temperature range, but as the temperature increases the desired working voltage may become significantly less than V_{cr}. The dashed lines in graph 1000 represent the desired working bias voltages for the EAM's in these packages through the desired operating temperature range of 0° C. to 70° C. These desired working bias functions may be desirably determined by the α crossing point of the lowest temperature in the temperature range (e.g., 0° C. in FIG. 10) and a predetermined slope, which may be determined empirically for the specific material system of the EAM.

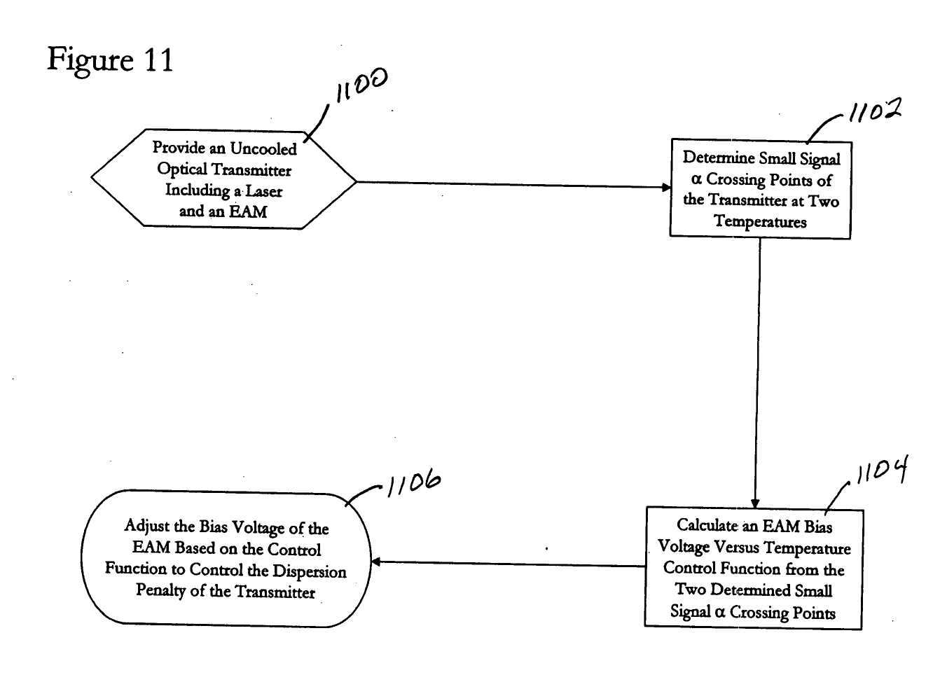

FIG. 11 is a flowchart illustrating an exemplary method of using the a crossing point variation of the EAM to control the dispersion penalty of an exemplary uncooled optical transmitter. An optical transmitter including a laser and an EAM is provided, step 1100. Two voltage values for the α crossing point may be determined at separate temperatures within the estimated operating temperature range of the EAM, step 1102. The two selected temperatures are desirably near the ends of the estimated operating temperature range. Alternatively, a single α crossing point voltage may be determined for the lowest temperature in the temperature range. A linear EAM bias voltage versus temperature control function is then calculated for all the temperatures within the temperature range, step 1104. Control of the dispersion penalty of the exemplary uncooled optical transmitter may then be achieved by adjusting the EAM bias voltage to maintain a constant α, using bias voltages from the current temperature and the calculated control function.

The laser, SOA and EAM of an exemplary laser integrated module transmitter configuration may each be formed with a quantum well structure. It is noted that such quantum well structures may be sensitive to temperature and, therefore, sub-components designed to operate at higher temperatures in uncooled applications may not operate well at low temperatures outside of the designed range. This issue may be particularly important for EAM's. Generally during high power, long reach, operation low temperature performance of the sub-components is not an issue, but situations may exist, due to environmental or other circumstances, in which these issues may arise. One exemplary solution is to provide for temperature control through heating with either a small thermoelectric cooler (TEC) or a resistive heater mounted to the underside (or the middle of) the platform under the EAM. Reduced power budgets for both transmitters and transponders are desirable, particularly in small form factor packages. Therefore, a resistive heater may be desirable due to its efficiency of energy conversion compared to a TEC.

Therefore an uncooled, long reach transmitter or a transponder, configured in an exemplary laser integrated module configuration, may be designed to have high reliability, as well as allowing control of the dispersion penalty and output power flatness of the device. Further, such an exemplary configuration may be packaged in a small form factor package due to reduce heat dissipation requirements.

Although the invention is illustrated and described herein with reference to specific embodiments, the invention is not intended to be limited to the details shown. Rather, various modifications may be made in the details within the scope and range of equivalents of the claims and without departing from the invention.

1. A method for substantially maintaining a dispersion penalty of an uncooled optical transmitter within a predetermined temperature range, the uncooled optical transmitter including a laser and an electroabsorption modulator (EAM), the method comprising the steps of:
a) determining small signal a crossing points at two temperatures within the predetermined temperature range;
b) calculating an EAM bias voltage versus temperature control function based on the two small signal α crossing points determined in step (a); and
c) adjusting the bias voltage of the EAM based on the EAM bias voltage versus temperature control function determined in step (b) to substantially maintain the dispersion penalty of the uncooled optical transmitter within the predetermined temperature range.

2. The method according to claim 1 wherein the EAM bias voltage versus temperature control function determined in step (b) is linear.

3. The method according to claim 1 wherein the maintained dispersion penalty of the uncooled optical transmitter is less than 2 dB for 1600 ps/nm data transmission at 10 Gb/s.

4. A method for substantially maintaining a dispersion penalty of an uncooled optical transmitter within a predetermined temperature range, the uncooled optical transmitter including a laser and an electroabsorption modulator (EAM) formed using a selected material system, the method comprising the steps of:
a) determining small signal a crossing points a lowest temperature of the predetermined temperature range;
b) calculating an EAM bias voltage versus temperature control function based on the small signal α crossing points determined in step (a) and a predetermined slope, the predetermined slope based on the selected material system; and
c) adjusting the bias voltage of the EAM based on the EAM bias voltage versus temperature control function determined in step (b) to substantially maintain the dispersion penalty of the uncooled optical transmitter within the predetermined temperature range.

5. The method according to claim 4 wherein the EAM bias voltage versus temperature control function determined in step (b) is linear.

6. The method according to claim 4 wherein the maintained dispersion penalty of the uncooled optical transmitter is less than 2 dB for 1600 ps/nm data transmission at 10 Gb/s.

7. An uncooled long reach optical transmitter, comprising;
an uncooled laser source to produce a laser beam;
an uncooled semiconductor optical amplifier (SOA) optically coupled to the uncooled laser source to amplify the laser beam; and
an uncooled electroabsorption modulator (EAM) optically coupled to the uncooled SOA to modulate the amplified laser beam.

8. The uncooled long reach optical transmitter according to claim 7, further comprising an optical isolator located between the uncooled laser source and the uncooled SOA to substantially reduce optical feedback of the laser beam into the uncooled laser source.

9. The uncooled long reach optical transmitter according to claim 7, wherein the uncooled laser source and the uncooled SOA are monolithically integrated.

10. The uncooled long reach optical transmitter according to claim 9, further comprising an optical isolator located between the uncooled SOA and the uncooled EAM to substantially reduce optical feedback of the amplified laser beam into the uncooled laser source.

11. The uncooled long reach optical transmitter according to claim 7, wherein the uncooled SOA and the uncooled EAM are monolithically integrated.

12. The uncooled long reach optical transmitter according to claim 7, wherein the uncooled laser source, the uncooled SOA, and the uncooled EAM are monolithically integrated.

13. The uncooled long reach optical transmitter according to claim 12, further comprising an optical isolator configured to receive the modulated laser beam to substantially reduce optical feedback of the modulated laser beam into the uncooled laser source.

14. The uncooled long reach optical transmitter according to claim 7, further comprising an optical power detector optically coupled to the uncooled EAM to monitor output power of the modulated laser beam.

15. The uncooled long reach optical transmitter according to claim 7, further comprising a temperature insensitive wavelength detector optically coupled to the uncooled EAM to monitor a peak output wavelength of the modulated laser beam.

16. An uncooled long reach optical transponder, comprising;
a PIN photodiode receiver;
modulation circuitry electrically coupled to the PIN photodiode receiver and adapted to provide a modulation signal responsive to an incident optical signal which is incident on the PIN photodiode receiver;
an uncooled laser source to produce a laser beam;
an uncooled semiconductor optical amplifier (SOA) optically coupled to the uncooled laser source to amplify the laser beam; and
an uncooled electroabsorption modulator (EAM) optically coupled to the SOA and electrically coupled to the modulation circuitry;
wherein the uncooled EAM modulates the amplified laser beam in response to the modulation signal to form an output optical signal of the uncooled long reach optical transponder.

17. A method for substantially maintaining an output power of an uncooled optical transmitter within a predetermined temperature range, the uncooled optical transmitter including a laser and a semiconductor optical amplifier (SOA), the method comprising the steps of:
a) setting an initial laser bias current of the laser and an initial SOA bias current of the SOA;
b) measuring the output power of the uncooled optical transmitter; and
C) adjusting the SOA bias current based on the output power measured in step (b) to substantially maintain the output power of the uncooled optical transmitter.

18. A method for improving transmitter reliability of an uncooled long reach optical transmitter operating substantially at a predetermined output power, the uncooled long reach optical transmitter including a laser and a semiconductor optical amplifier (SOA), the method comprising the steps of:
a) operating the laser to produce a reduced power laser beam, thereby improving laser reliability of the laser; and
b) controlling an SOA bias current to amplify the reduced power laser beam in the SOA and substantially maintain the predetermined output power;
wherein the SOA is sufficiently long to provide the amplification of step (b) and maintain a reduced current density within the SOA, thereby improving SOA reliability of the SOA.

19. A method according to claim 18 wherein the uncooled long reach optical transmitter further includes an electroabsorption modulator (EAM), and the method further comprises the step of:
c) controlling an EAM bias voltage to substantially maintain a substantially constant dispersion penalty of the uncooled optical transmitter.

20. A method for manufacturing a monolithic laser integrated module for use in an uncooled long reach optical transmitter, the method comprising the steps of:
a) providing a substrate base having a substrate base index of refraction;
b) forming a grating layer over the substrate base, the grating layer having a grating index of refraction different from the substrate base index of refraction;
c) defining and etching the grating layer to form a grating base section having a grating period;
d) forming a top substrate layer over the substrate base and the grating base sections, the top substrate layer having a substrate index of refraction different from the grating index of refraction and a top surface;
e) forming a quantum well layer on the top surface of top substrate layer having a waveguide index of refraction different from the substrate index of refraction and including a plurality of sub-layers forming a quantum well structure, each of the sub-layers including a waveguide material;
f) forming a semiconductor layer on the quantum well layer, the semiconductor layer having a semiconductor layer index of refraction different from the waveguide index of refraction;
g) defining and etching the quantum well layer and the semiconductor layer to form a distributed feedback laser section, a semiconductor optical amplifier (SOA) section, and an electroabsorption modulator (EAM) section in the quantum well layer;
h) depositing a distributed feedback laser electrode on the semiconductor layer corresponding to a portion of the distributed feedback laser section of the quantum well layer;
i) depositing an SOA electrode on the semiconductor layer corresponding to a portion of the SOA section of the quantum well layer; and
j) depositing an EAM electrode on the semiconductor layer corresponding to the EAM section of the quantum well layer.

21. A method according to claim 20, wherein step (e) includes the steps of:
e1) forming at least one patterned growth retarding mask on a laser area and an SOA area of the top surface of the top substrate layer; and
e2) forming the quantum well layer on the top surface of the top substrate layer by selective area growth, the quantum well layer including;
a laser portion formed over at least the grating base section and adjacent to the laser area of the top surface of the top substrate layer, the laser portion having a laser thickness;
an SOA portion formed adjacent to the SOA area of the top surface of the top substrate layer, the SOA having a SOA thickness; and
an EAM portion having an EAM thickness which is less than the laser thickness and the SOA thickness.

22. A method according to claim 20, wherein the sub-layers of the quantum well layer include at least one of strained InGaAlAs sub-layers and graded InGaAlAs sub-layers.

23. A method according to claim 20, wherein:
steps b, d, e, and f use metal organic chemical vapor deposition (MOCVD); and
step c uses at least one of phase mask lithography and anisotropic etching.
